(19) United States
(12) Patent Application Publication
(10) Pub. No.: US 2008/0131792 A1
(43) Pub. Date: Jun. 5, 2008

(54) Method of Correcting Photomask Defect

(76) Inventors: Osamu Takaoka, Chiba-shi (JP); Junichi Tashiro, Chiba-shi (JP)

Correspondence Address: BRINKS HOFER GILSON & LIONE, P.O. BOX 10395, CHICAGO, IL, 60610, US

(21) Appl. No.: 11/946,377

(22) Filed: Nov. 28, 2007

(30) Foreign Application Priority Data
Nov. 29, 2006 (JP) JP2006-322290
Oct. 30, 2007 (JP) JP2007-281617

(51) Int. Cl. G03F 1/00

(52) U.S. Cl. 430/5; 977/742

(57) ABSTRACT

In a micromachining apparatus equipped with an AFM having a plurality of independently actuatable probes, which uses an electron beam or a helium ion beam produced by a gas field ion source, an isolating pattern including a defect is grounded by bringing the conducting probe into contact with the pattern, and then the opaque defect is corrected while the charge-up by an electron beam or gas ion beam is prevented. In the case where there are isolating patterns in an observation range and the effect of the charge-up arises even when the isolating pattern including a defect is grounded, the respective isolating patterns are grounded by the plurality of conducting probes thereby to suppress the effect of the charge-up.

### RELATED APPLICATIONS

This application claims priority under 35 U.S.C. §119 to Japanese Patent Application Nos. JP2006-322290 filed Nov. 29, 2006 and JP2007-281617 filed Oct. 30, 2007, the entire content of which is hereby incorporated by reference.

### BACKGROUND OF THE INVENTION

The present invention relates to a method of correcting a defect of a photomask using an electron beam or a helium ion beam produced by a gas field ion source in a micromachining apparatus which uses the electron beam or helium ion beam produced by the gas field ion source.

Lithography has coped with a demand for further scaling-down of semiconductor integrated circuits by making the wavelength of a light source of a reduced-size-projection aligner shorter and NA larger. Conventionally, correction of a defect of a photomask, which is required to be non-defective as an original pattern plate for transfer by a reduced-size-projection aligner, has been performed by use of a laser or focused ion beam. However, in regard to lasers, it has been impossible to correct a defect of a cutting-edge fine pattern because of the insufficient resolution. As for focused ion beams, it is becoming a problem that injection of gallium used for a primary beam causes an imaging damage (reduction in transmissivity) of a glass portion as the wavelength of a light source of a reduced-size-projection aligner is made shorter. Hence, a technique for correcting a defect, which enables correction of a defect of a fine pattern, but causes no imaging damage, has been required. Because of such background, an apparatus for correcting a defect of a photomask by use of an electron beam has been developed recently, in which an opaque defect is corrected by gas-assist etching with an electron beam, and a clear defect is corrected through deposition of a light-shielding film by electron beam CVD (K. Edinger, H. Becht, J. Bihr, V. Boegli, M. Budach, T. Hofmann, H. P. Coops, P. Kuschnerus, J. Oster, P. Spies, and B. Weyrauch, J. Vac. Sci. Technol. B22 2902-2906 (2004)). Aside from an electron beam, it has been known that use of an inert gas ion beam causes no imaging damage (B. W. Ward, John A, Notte, and N. P. Economou, “Helium ion microscope: A new tool for nanoscale microscopy and metrology”, J.Vac.Sci. Technol. B, Vol 24, No. 6, November/December 2006). When an electron beam or inert gas ion beam is used for imaging and machining, high resolution is obtained and the reduction in transmissivity owing to implantation of gallium is never caused.

In a conventional method of correcting a defect of a photomask using an electron beam or a helium ion beam obtained from a gas field ion source, when a relatively small metallic film pattern such as an isolating pattern is irradiated with the beam thereby to correct a defect, the irradiation of the electron beam or helium ion beam which can be obtained from a gas field ion source causes the buildup of charge resulting in the charge-up. This is because a photomask has a glass with a metallic film for blocking light deposited thereon. The charge-up deteriorates the quality of a secondary electron image and causes the drift, reducing the precision of machining. This has been a problem.

In addition, as an image of an electron beam or a helium ion beam obtained from a gas field ion source has no information about a height, detection of an end point is performed according to the differences among intensities of secondary electron emission, which depend on the material. However, as to an isolating defect and a defect in an isolating pattern, which are easily charged up, a mistake has been often made in detecting an end point. Also, there has been a problem that in the cases of a combination of materials, which pose a small difference in secondary electron emission intensity originally, and the same material such as a glass bump of a Levenson mask, an end point cannot be detected with the difference in secondary electron emission intensity depending on the material.

Recently, a four-terminal measurement has been coming into practice with a scanning electron microscope additionally equipped with the function of a multi-probe STM (Scanning Probe Microscope) which can be actuated independently of the scanning electron microscope for the purpose of clarifying electrical properties of a fine area (NANOTECHNOLOGY NO TAMENO SOUSA KENBIKYO GIJUTSU (Scanning Microscope Technique for nanotechnology), edited by Nihon Hyomen Kagaku Kai (the Surface Science Society of Japan), 143-151 (2004), Maruzen). The apparatus is one which has four probes of a compact STM (actuatable independently) arranged with a layout such that the individual probes can approach an electron beam-irradiated position on a sample stage of a scanning electron microscope, and is capable of performing a four-terminal measurement of a fine area because it can independently control the respective probes to a desired position. The function of monitoring the position of each probe by an electron beam, the downsizing of the actuating part and use of a carbon nanotube as a probe are making it possible to bring the probe to a distance of 20 nm or smaller from the electron beam-irradiated position (Masakazu Aono, Tomonobu Nakayama, Yuji Kuwahara, and Megumi Akai, OYO BUTURI Vol. 75, 285-295 (2006)). Also, as for an atomic force microscope (AFM), use of a self-detection-type cantilever, which can be downsized, makes it possible to materialize a multi-probe AFM (i.e. AFM having a plurality of probes which can be actuated independently) even with the same configuration.

Hence, the invention aims to provide a method of correcting a defect of a photomask by use of an electron beam or a helium ion beam, which can solve the above-described problems, and prevent an isolating pattern or an isolating defect from being charged with electrons by a combination of a micromachining apparatus using an electron beam or a helium ion beam obtained from a gas field ion source and a multi-probe AFM while a defect of a mask is corrected by the beam, and therefore which can prevent the deterioration of the image quality and machining precision and further enables precise detection of an end point.

### SUMMARY OF THE INVENTION

To solve the above problems, according to the method of correcting a defect of a mask by use of an electron beam or a helium ion beam obtained from a gas field ion source of the invention, a scanning electron microscope is integrated with an AFM having a plurality of self-detection-type cantilevers, which each have a probe in its end portion and can be actuated independently. Specifically, the respective probes of AFM are applied to suppression of charge-up of an isolating pattern, detection of a machining end point, removal of a contamination, and removal of an opaque defect of a material which cannot be cut with an electron beam, which are issues of a method of correcting a defect of a mask by use of an electron beam or a helium ion beam.

Specifically, an arrangement that a defect is corrected while charge-up by a beam is prevented is made by bringing, of a plurality of probes of an AFM which can be independently driven to a beam-irradiated position of a micromachining apparatus using an electron beam or a helium ion beam obtained from a gas field ion source, a conducting probe into contact with an isolating pattern including a defect, thereby to ground the isolating pattern.

In this time, in the case where there are isolating patterns in an observation range and the effect of the charge-up arises even when the isolating pattern including a defect is grounded, the respective isolating patterns are grounded by the conducting probes, thereby suppressing the effect of the charge-up.

Also, a defect is corrected while the height of the defect which is being machined with an electron beam or a helium ion beam obtained from the gas field ion source is measured with, of the probes, another probe different from the conducting probes.

Further, a piece of conducting carbon nanotube or carbon nanotube coated with a conducting film is used as the conducting probe. As a result, the tip of the probe can be made smaller, and therefore charge-up of densely packed isolating patterns or a small isolating pattern can be suppressed.

In addition, a piece of carbon nanotube or a carbon fine probe manufactured by deposition by an electron beam or deposition by a helium ion beam obtained from a gas field ion source is used as the probe for measuring the height of a defect. Thus, the height can be measured even when a machining spot to be measured is a hole with a high aspect ratio.

As the cantilever having a probe for measuring the height of a defect is used a bimorph-type one. Thus, the time for making the probe approach a machining position and retracting it therefrom can be shortened by extending and curving the cantilever, and therefore it becomes possible to shorten the time for detection of a machining end point. Note that the bimorph-type cantilever is a laminate of members different in linear expansion coefficient, and is curved when it is heated by e.g. energizing the implanted diffused resistor. The amount of curving can be controlled by controlling the temperature (or the electric current in the case of heating by the energization). Therefore, when it is not required to detect an end point, the cantilever is curved and retreated from the electron beam irradiation path; when detection of an end point is needed, the cantilever is extended and made to approach a defect, followed by performing detection of the end point while the height of the defect which is being machined by etching with an electron beam or a helium ion beam obtained from a gas field ion source is measured.

Charge-up owing to excessive accumulation of charges can be prevented by using a conducting probe to secure electrical continuity with an isolating pattern. As suppression of charge-up can eliminate the drift resulting from charge-up and improve the image quality, it is avoided to make a mistake in recognizing a defect and thus correction of a defect can be performed with high precision. Use of a scanning probe microscope unit to adjust a grounding position avoids the difficulty of adjusting the position as a manipulator inserted at an oblique angle has, and therefore the position can be adjusted by simple X, Y and Z movements easily.

In addition, measurement of the height of a machining position enables detection of an end point with a higher reliability in comparison to the detection of a machining end point based on the dependence of secondary electron emission on a material. Further, even when a defective portion is made of the same material as that of the substrate as in the case of correcting a glass bump of a Levenson mask, an end point can be detected.

Use of a piece of carbon nanotube as the conducting probe allows even a small isolating pattern to be grounded. In addition, as the probe takes a shape having a high aspect ratio, a plurality of spots can be grounded even when isolating patterns are packed densely. An electron beam and a helium ion beam never destroy carbon nanotube through irradiation unlike a gallium ion beam because they are small in mass.

Use of a piece of carbon nanotube or carbon fine probe manufactured by electron beam or helium ion beam deposition for detection of an end point, which has a small tip diameter and a high aspect ratio, allows the height to be determined precisely even when a machining spot to be measured has a high aspect ratio.

Because of use of a probe mounted on a bimorph-type cantilever for detection of an end point, if the position to approach a defect is determined once, the escape and approach of the probe can be performed at a high speed by ON/OFF of application of electricity to the bimorph-type cantilever without moving the stage for the second and subsequent times. Thus, the time for moving the XY stage and regrounding can be eliminated, and therefore the time for detection of an end point can be shortened.

### BRIEF DESCRIPTION OF THE DRAWINGS

FIG. 1 is a schematic sectional view for explaining the case of correcting an opaque defect in an isolating pattern according to the invention.

FIG. 2 is a schematic sectional view for explaining the case of correcting a clear defect in an isolating pattern according to the invention.

FIG. 3 is a schematic sectional view for explaining the case of performing detection of an end point by measuring a height according to the invention.

FIG. 4 is a schematic sectional view for explaining the case of suppressing the charge-up of a fine isolating pattern by a probe of conducting carbon nanotube or carbon nanotube coated with a conducting film.

FIG. 5 is a schematic sectional view for explaining the case of using a probe having a small diameter and a high aspect to measure the height of a shape with a high aspect.

FIGS. 6A and 6B are schematic sectional views for explaining the case of using a bimorph-type cantilever to measure the height of a machining spot.

### DETAILED DESCRIPTION OF THE PREFERRED EMBODIMENT

The embodiments of the invention will be described below in detail with reference to the drawings.

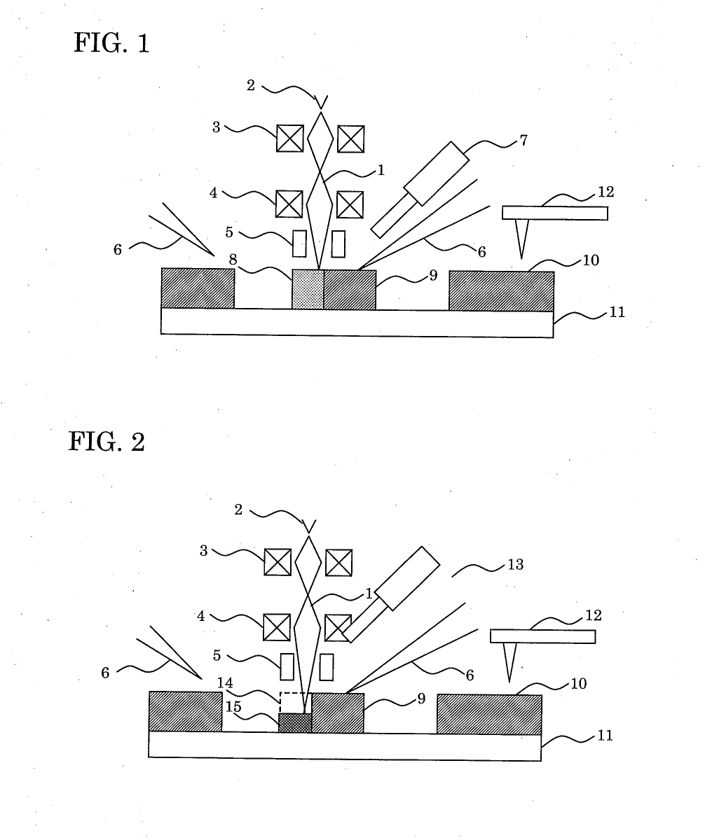

FIG. 1 is a schematic sectional view for explaining the case of correcting an opaque defect in an isolating pattern, and FIG. 2 is a schematic sectional view for explaining the case of correcting a clear defect in an isolating pattern.

A photomask composed of a pattern 10 and a glass substrate 11, which has a defect, is loaded into an electron beam micromachining apparatus having a light-shielding-film-making feedstock gas introduction system 13 and a gas introduction system 7 for a gas-assist etching, followed by transporting a stage to a position of a defect which has been found by an apparatus for defect inspection. Then, an electron beam 1 is irradiated on an opaque defect or a clear defect to correct them. The electron beam 1 is generated from an electron source 2. A condenser lens 3 condenses the electron beam 1, and an objective lens 4 focuses it on the defect. A polarizer 5 deflects the electron beam on a desired area of the defect.

In the case where an opaque defect 8 or a clear defect 14, which is to be corrected, is adjacent to an isolating defect or an isolating pattern 9, the charge-up by the electron beam worsens the image quality, and precise machining cannot be performed in machining by an electron beam because of the drift of the electron beam, an electron beam micromachining apparatus with the function of an AFM having a plurality of independently actuatable probes is used to correct the defect while the charge-up by the electron beam is prevented by bringing a conducting probe 6 of the plurality of multi-probes into contact with an isolating pattern 9 including the opaque defect 8 or clear defect 14 thereby to ground the isolating pattern. In the case of an opaque defect of FIG. 1, under the condition where the isolating pattern 9 is grounded by bringing the conducting probe 6 into contact with the isolating pattern 9 during the time of irradiation of an electron beam, thereby suppressing the charge-up, an image is acquired and then the opaque defect area 8 is recognized. Next, an assist etching gas is introduced through the gas introduction system 7, and only the recognized opaque defect area is irradiated with an electron beam 1 selectively, whereby the opaque defect 8 is removed. In the case of a clear defect of FIG. 2, an image is acquired and the clear defect 14 is recognized under the condition where the isolating pattern 9 is grounded by the conducting probe 6 thereby to suppress the charge-up thereof, as in the case of an opaque defect. Next, a light-shielding-film-making feedstock gas is introduced through the gas introduction system 13, only the recognized clear defect 14 is irradiated with the electron beam 1 selectively, and the light-shielding film 15 is deposited, whereby the clear defect 14 is corrected.

In the case where there are plurality of isolating patterns in a defect observation range and the effect of charge-up arises even when the isolating pattern including a defect is grounded, the respective isolating patterns are grounded by the conducting probes thereby to suppress the effect of charge-up. In the case where the isolating defects or isolating patterns 9 are small or densely packed, and it is difficult to perform grounding by the conventional conducting probe 6, probes 16 of conducting carbon nanotube or carbon nanotube coated with a conducting film, which are small in tip diameter and superior in aspect ratio, are used to ground the isolating patterns, as shown in FIG. 4.

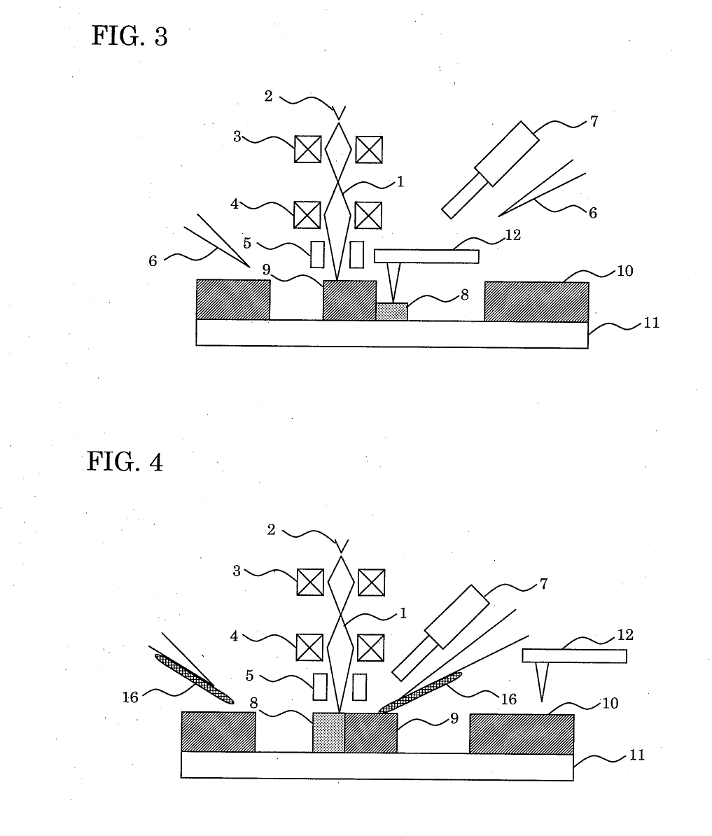

FIG. 3 is a schematic sectional view for explaining the case of performing detection of an end point by measuring the height in correction of an opaque defect by an electron beam.

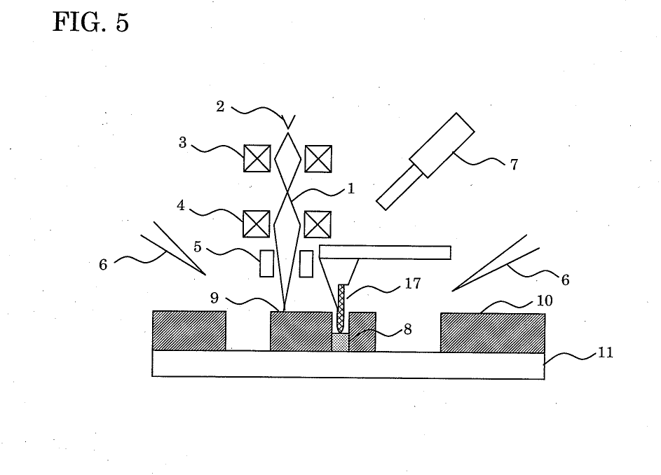

In the case where it is required to detect a machining end point in correction of an opaque defect, machining by an electron beam 1 is suspended, the stage (not shown) on which a glass substrate 11 is placed is transported by an offset between an electron beam-irradiated position and an AFM probe thereby to move the opaque defect underneath the position of the AFM probe, and then the height of the opaque defect 8 which is being machined through electron beam etching is measured by the AFM probe 12 attached perpendicularly to the mask for measuring a height, as shown in FIG. 3. In the case where the opaque defect 8 still remains after the measurement, the stage is returned by the offset, followed by confirming the area to be machined by the electron beam 1 again, calculating a required amount of irradiation current from the height of the opaque defect 8 obtained by AFM measurement, and again correcting the defect by selectively irradiating the defect with the electron beam 1 under the atmosphere of the assist etching gas. Until the machining reaches an end point, the measurement of the height and additional machining are repeated. In the case where a spot to be measured in height is in a high-aspect form such as the bottom of a hole, a high-aspect probe 17 for measuring a height, which has a small tip diameter and a high aspect ratio and is made from a piece of carbon nanotube or a piece of carbon manufactured by electron beam deposition, is used to measure the height, as shown in FIG. 5.

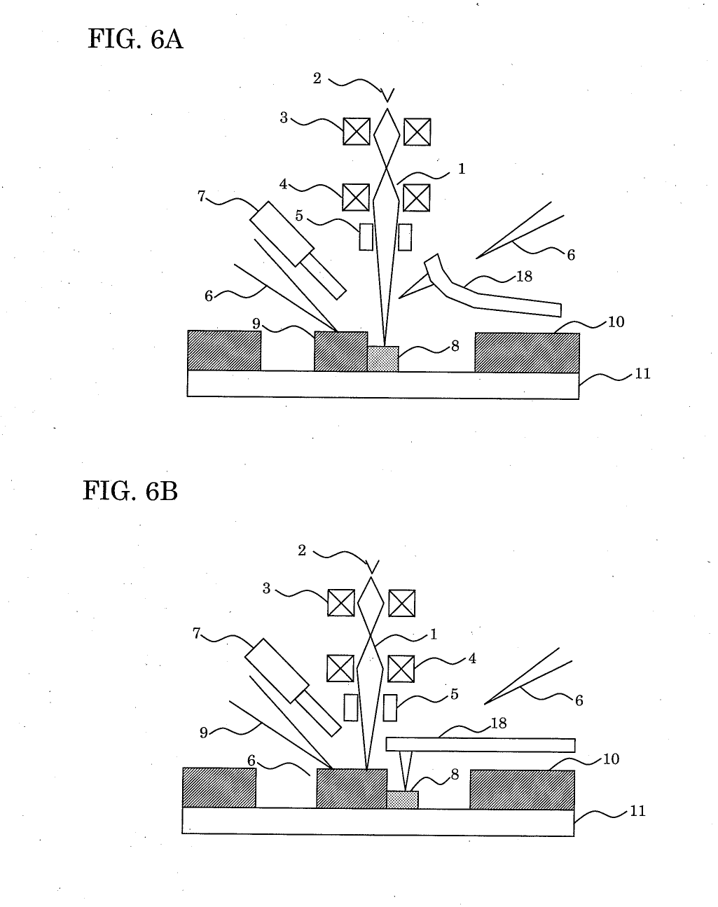

In the case where it is necessary to shorten the time for detection of an end point, a bimorph-type cantilever 18, which allows retraction and approach of a probe at a high speed, is used as the cantilever of the probe for measuring a height as shown in FIGS. 6A and 6B. As the bimorph is used e.g. a laminate of an Ni substrate and an Si substrate. The position for the probe to approach a defect is determined in the condition where the bimorph-type cantilever 18 is extended once. In machining by the electron beam 1, a diffused resistor formed in a surface of the cantilever, which serves as a heater, is energized thereby to increase its temperature, and the cantilever 18 is curved utilizing the difference in linear expansion coefficient between Ni and Si, whereby the probe is retracted from the electron beam irradiation path, as shown in FIG. 6A. In detection of an end point, the energization to the cantilever 18 is cut off to lower the temperature and extend the cantilever 18, whereby the probe is arranged just above the position of the opaque defect 8, as shown in FIG. 6B. By making an arrangement like this, the movement of the XY stage incident to the detection of an end point by an AFM, and the time for regrounding can be eliminated, and therefore the time for detection of an end point can be shortened.

As a matter of course, an AFM probe can be used to remove a soft contamination on a mask, and to relocate a contamination whose adhesive force is weak. By combining a cantilever having a large spring constant and a rigid probe, it becomes possible to raze a hard contamination on a mask, whose adhesive force is strong.

Further, a combination of a cantilever having a large spring constant and a rigid probe can be applied to removal of an opaque defect of a material which cannot be razed by electron beam etching because there is no adequate assist etching gas.

While the method of correcting a defect of a photomask using an electron beam micromachining apparatus has been described so far, the goal of the invention can be also achieved by a micromachining apparatus which has a gas field ion source instead of the electron beam micromachining apparatus.

Now, a micromachining apparatus equipped with a gas field ion source will be described. With the gas field ion source, the diameter of the beam can be narrowed down to 1 nanometer or below. This is because the source size can be reduced to 1 nanometer or below, and the broadening of the ion beam energy can be made not more than 1 electron volt. As the diameter of the beam can be made smaller as described above, it is possible to perform micromachining (e.g. etching and deposition) on a sample.

The operational principle of the gas field ion source is as follows. A very small amount of gas (e.g. helium gas) is supplied from a gas-supplying source to an emitter which is cooled by coolant such as liquid nitrogen and sharpened with the level of an atomic scale. When a voltage is applied between the emitter and an extractor electrode, an extremely strong electric field is formed around the sharply pointed emitter tip. Helium atoms attracted by the emitter are ionized and emitted in an ion beam. The tip of the emitter is shaped into an extremely sharpened form, and the helium ions are launched from the tip. On this account, the energy distribution of an ion beam launched from the gas field ion source is extremely narrow. Hence, an ion beam having a smaller diameter and a higher brightness can be obtained in comparison to conventional plasma gas ion sources and liquid-metal ion sources.

In the case where the micromachining apparatus with the gas field ion source as described above is used instead of an electron beam micromachining apparatus, beam irradiation never causes destruction of the carbon nanotube even when a piece of carbon nanotube is used as a conducting probe because the effect of sputtering of helium gas ions is smaller than that of gallium ions. Therefore, a defect of a mask can be corrected by a combination of the micromachining apparatus with the gas field ion source and the multi-probe AFM as in the case of the electron beam micromachining apparatus. In other words, even when a helium ion beam produced by a gas field ion source is used instead of the electron beam 1 as shown in FIGS. 1 to 6, the goal hereof can be achieved.

What is claimed is:

1. A method of correcting a defect of a photomask in a micromachining apparatus equipped with an AFM having a plurality of independently actuatable probes, which uses an electron beam or a helium ion beam produced by a gas field ion source, comprising
when correcting a defect of a photomask by an electron beam or a helium ion beam produced by the gas field ion source, bringing a conducting probe of the plurality of probes into contact with an isolating pattern including the defect to ground the isolating pattern, whereby the defect is corrected while charge-up by the electron beam or helium ion beam produced by the gas field ion source is prevented.

2. The method of correcting a defect of a photomask according to claim 1, wherein the defect is corrected while a height of the defect which is being machined by the electron beam or helium ion beam produced by the gas field ion source is measured with a probe of the plurality of probes different from the conducting probe.

3. The method of correcting a defect of a photomask according to claim 1, wherein the conducting probe is a piece of conducting carbon nanotube or carbon nanotube coated with a conducting film.

4. The method of correcting a defect of a photomask according to claim 2, wherein the conducting probe is a piece of conducting carbon nanotube or carbon nanotube coated with a conducting film.

5. The method of correcting a defect of a photomask according to claim 2, wherein the probe used to measure the height of the defect is a piece of carbon nanotube or a carbon fine probe manufactured by deposition by an electron beam or a helium ion beam produced by a gas field ion source.

6. The method of correcting a defect of a photomask according to claim 2, wherein a cantilever having the probe used to measure the height of the defect is a bimorph-type one, and in machining by the electron beam or helium ion beam produced by the gas field ion source, the cantilever is curved and retracted from an irradiation path for the electron beam or helium ion beam produced by the gas field ion source.
